(19) United States
(12) Patent Application Publication
(10) Pub. No.: US 2005/0071970 A1
(43) Pub. Date: Apr. 7, 2005

(54) Manufacturing method for electrodes that inhibit corona effect on ceramic capacitor

(76) Inventor: Wei-Hou Chang, Chung-Li (TW)

Correspondence Address: TROXELL LAW OFFICE PLLC, Suite 1404, 5205 Leesburg Pike, Falls Church, VA, 22041, US

(21) Appl. No.: 10/733,313

(22) Filed: Dec. 12, 2003

(30) Foreign Application Priority Data
Oct. 2, 2003 (TW) 92127314

(51) Int. Cl. H01L 21/00; H01G 9/00; H01L 21/64; H01G 7/00; H01L 21/20

(52) U.S. Cl. 29/25.02; 29/25.03; 29/25.42; 438/381

(57) ABSTRACT

A manufacturing method for electrodes that inhibit corona effect on ceramic capacitor is disclosed. It is mainly to coat the two electrodes of a ceramic capacitor (including AC ceramic capacitor and DC ceramic capacitor) by printing or chemical electroless plating and vapor deposition. Then, the coating overflow area of the ceramic capacitor is subject to polishing treatment, so the cross-section of the two electrodes of the ceramic capacitor is completely covered by conductive layer and electrode leakage is eliminated. Besides, withstanding voltage is thus increased and corona effect is inhibited.

### FIELD OF THE INVENTION

The present invention is related to a manufacturing method for electrodes of ceramic capacitors. Especially, it is a manufacturing method for electrodes that can inhibit corona effect on ceramic capacitors. The method allows the capacitor electrode surface coated with conductive paste to inhibit corona effect, so the withstanding voltage is raised.

### BACKGROUND OF THE INVENTION

In general, the manufacturing method for ceramic capacitor comprises green compact molding of ceramic powder sintering→cleaning→electrode formation→soldering pin Assemble→Coated of Enclosure→Curing of coated→electric testing→finished product. Particularly, the quality reliability of ceramic capacitor is completely determined by electrode formation and soldering pin. Traditionally, the electrode surface is coated with a conductive layer by printing or electroplating. It benefits solderability of soldering pin and provides connection interface between a capacitor and pins. Traditional electrode formation process only involved simple printing or electroplating, but did not emphasize the effect of coating area. As a consequence, corona effect takes place in the voids due to incomplete coating and affects withstanding voltage. It is necessary to make improvement on this aspect.

### SUMMARY OF THE INVENTION

In view of this, the inventor aimed to improve the withstanding voltage of ceramic capacitor by proposing a manufacturing method for electrodes to inhibit corona effect on ceramic capacitor. The process adopts printing or electroplating or vacuum deposition to coat electrode surface. Then the coating overflow area on the electrode of a capacitor is subject to polishing treatment. Therefore, the cross-section of the two electrodes of the ceramic capacitor is completely coated with conductive paste without leakage. Thus, withstanding voltage is raised and corona effect is inhibited.

### BRIEF DESCRIPTION OF THE DRAWINGS

FIG. 1 is a three-dimensional illustration for an electrode of a ceramic capacitor in the present invention.

FIG. 2 is a manufacturing process flow diagram for a preferred embodiment in the present invention.

FIG. 3 is a manufacturing process flow diagram for another preferred embodiment in the present invention.

FIG. 4 is an illustration of leakage of conductive paste at outer edge for another preferred embodiment in the present invention.

FIG. 5 is a manufacturing process flow diagram for another preferred embodiment in the present invention.

### DETAILED DESCRIPTION OF THE INVENTION

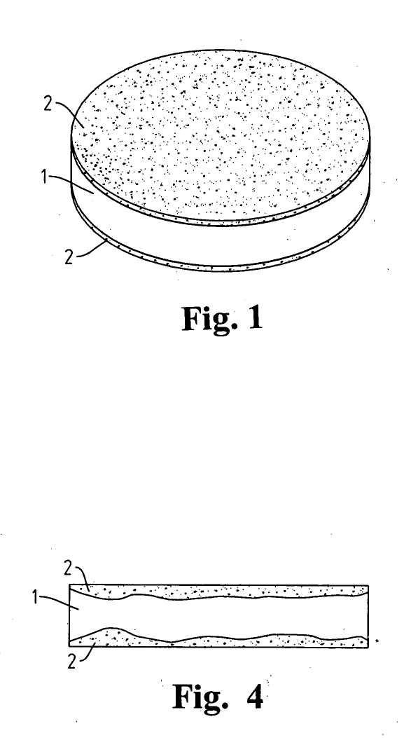

The manufacturing method for electrodes that inhibit corona effect on ceramic capacitor is mainly to coat the two electrodes of a ceramic capacitor with conductive paste by printing or chemical electroless plating and vapor deposition. Then, the coating overflow area of the ceramic capacitor is subject to polishing treatment, so the cross-section of the two electrodes 2 of the ceramic capacitor 1 is completely covered by conductive layer and electrode leakage is eliminated (as shown in FIG. 1). Besides, withstanding voltage is thus increased and corona effect is inhibited.

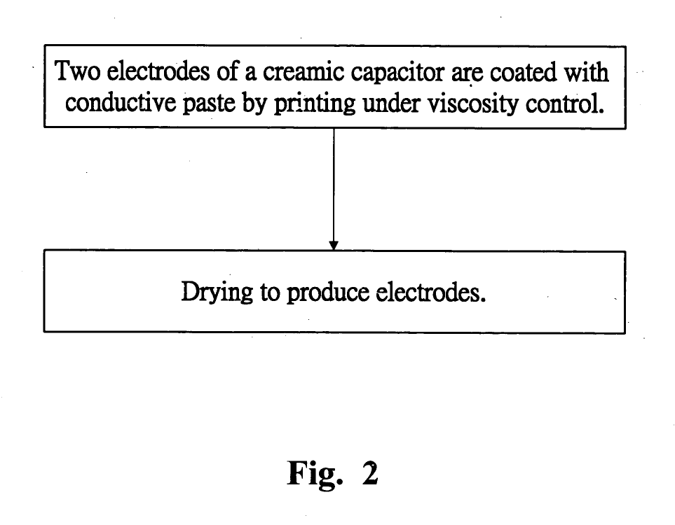

Please refer to FIG. 2, which is a manufacturing process flow diagram for a preferred embodiment in the present invention and involves procedures as follows:

The surface of the two electrodes of a ceramic capacitor is coated with conductive paste by a printing process under viscosity control. More specifically, the surface of electrodes of a common ceramic capacitor 1 sintered with diameter of 3 mm˜30 mm and thickness of 0.8 mm˜15 mm is coated with conductive silver or copper paste by a printing process under viscosity control. For example, if the surface of two electrodes of a ceramic capacitor 1 with diameter of 3 mm˜30 mm and thickness of 0.8 mm˜15 mm is coated with 1 um˜50 um thick electrode 2, the silver paste in the conductive paste takes up about 40%˜80% and has a viscosity about 10,000˜200,000 cps, so the silver paste is completely applied to the cross-section of the two electrodes of a ceramic capacitor 1 and does not create leakage problem. Another example is to use silver paste to coat 1 um˜50 um thick electrode 2 on the surface of two electrodes of a ceramic capacitor 1 with diameter of 3 mm˜30 mm and thickness of 0.8 mm˜15 mm by copper paste that takes up about 40%˜85% of the conductive paste and has a viscosity about 10,000˜200,000 cps. Thus, the copper paste is completely applied to the cross-section of two electrodes of the ceramic capacitor 1 without leakage problem.

In the step of sintering, the conductive paste covered two electrodes of the ceramic capacitor 1 is subject to sintering at 150˜850° C. to reduce into silver or copper electrode, so the cross-section of the two electrodes 2 is completely covered with conductive paste without leakage at outer edge and corona effect is inhibited.

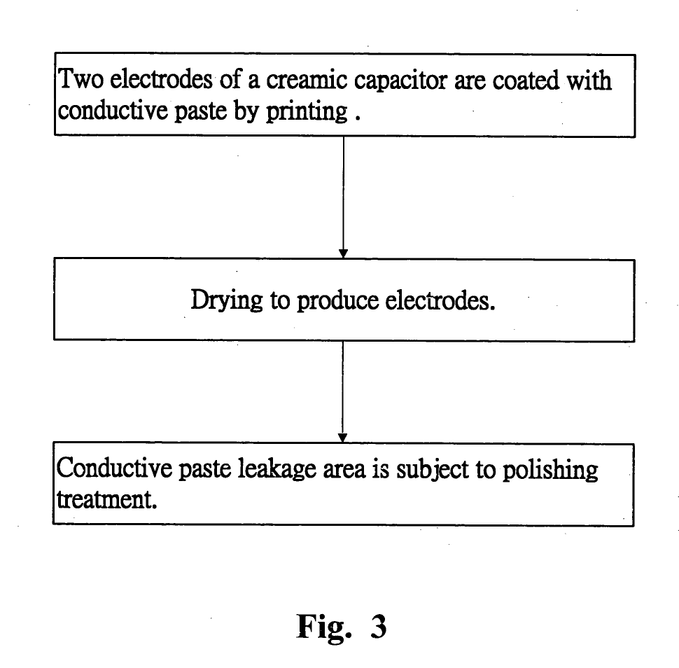

Please refer to FIG. 3, which is a manufacturing process flow diagram for another preferred embodiment in the present invention and involves procedures as follows:

The surface of the two electrodes of a ceramic capacitor is coated with conductive paste by a printing process. This is carried out by printing conductive silver or copper paste on the surface of electrodes of a common sintered ceramic capacitor 1 with diameter of 3 mm˜30 mm and thickness of 0.8 mm˜15 mm. The viscosity of the silver or copper paste is controlled to be about 8,000˜150,000 cps, so the surface of the two electrodes 2 (as shown in FIG. 4) of a ceramica capacitor is a 1 μm˜50 μm thick conductive layer without any leakage problem.

The electrodes of the ceramic capacitor 1 are subject to sintering at 150˜850° C. to reduce into silver or copper electrodes.

The leakage electrode layer at outer edge of the ceramic capacitor is subject to polishing treatment by a 200˜1500 μm, 5˜100 rpm diamond polishing wheel. The coating overflow area at outer edge of the ceramic capacitor 1 is polished by 0.05 mm˜1.0 mm in depth. Therefore, the electrode 2 (as shown in FIG. 1) is successfully produced to inhibit corona effect by coating conductive paste on the cross-section of the two electrodes of the ceramic capacitor 1 without leakage problem.

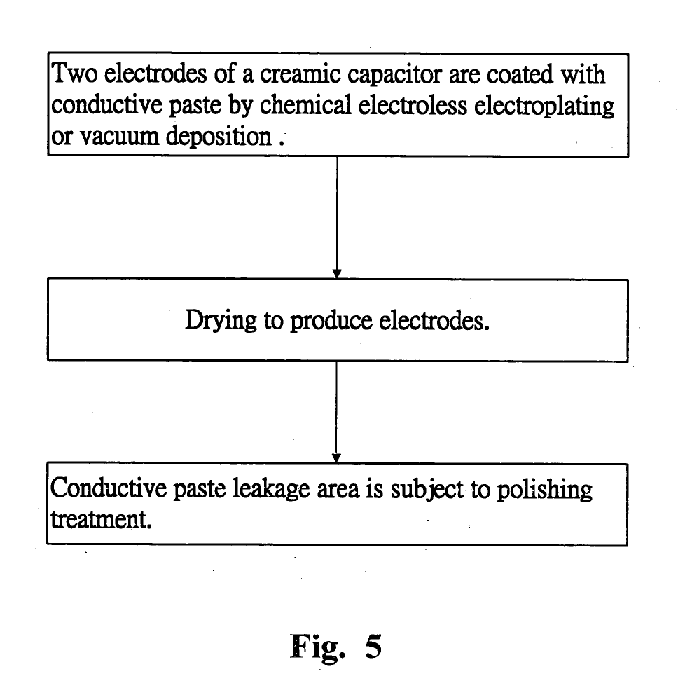

Please refer to FIG. 5, which is a manufacturing process flow diagram for another preferred embodiment in the present invention and involves procedures as follows:

The surface of the two electrodes of a ceramic capacitor 1 with diameter of 3 mm˜30 mm and thickness of 0.8 mm˜15 mm is coated with conductive paste by an electroplating process. The electrode surface 1 is subject to chemical electroless electroplating or vacuum deposition to form 1 μm˜15 μm thick electrode 2.

The conductive paste covered electrodes of the ceramic capacitor 1 are subject to drying at 50˜250° C. for to reduce into silver or copper electrodes 5-120 minutes.

The leakage electrode layer at outer edge of the ceramic capacitor is subject to polishing treatment by a 200˜1500 μm, 5˜100 rpm diamond polishing wheel. Therefore, the electrode 2 is successfully produced to inhibit corona effect by coating conductive paste on the cross-section of the two electrodes of the ceramic capacitor 1 without leakage problem.

From the above examples, it is known that the manufacturing method for electrodes that inhibit corona effect on ceramic capacitor is mainly to coat the two electrodes of a ceramic capacitor by printing or chemical electroless plating and vapor deposition. Then, the coating overflow area of the ceramic capacitor is subject to polishing treatment, so the cross-section of the two electrodes of the ceramic capacitor is completely covered by conductive layer and electrode leakage is eliminated. Besides, withstanding voltage is thus increased and corona effect is inhibited. These benefits would not be achieved on a 2 mm thick and 10,000 pf capacitor by a traditional method of printing or electroplating because the surface of the two electrodes would not be covered by conductive layer. Unless the capacitor diameter is made to be 15 mm. However, by using the manufacturing method in the present invention to completely cover the electrode surface with conductive layer, the capacitor diameter only needs 13.4 mm to achieve the above-mentioned benefits. Apparently, for the same performance requirement of a capacitor, the present invention offers a method to reduce material cost and improve product competitiveness. The present invention proves to have a significant practical value.

To sum up the above description, the present invention provides a manufacturing method for electrodes that inhibit corona effect on ceramic capacitor. Through following soldering pins and packaging, the size of ceramic capacitor product is reduced in diameter and thickness by 5˜20%, so the manufacturing cost is reduced by 20˜35%. More importantly, corona effect is eliminated and withstanding voltage is increased by 20˜35%. The present invention proves to have a significant practical value with utilization and progressiveness. The present invention is believed to meet patent requirements. A patent application is filed.

1-6. (canceled)

7. A manufacturing method for electrodes that inhibit a corona effect on a ceramic capacitor, which comprises the following steps:
a) coating a surface of two electrodes of a ceramic capacitor with a conductive paste utilizing a printing process under viscosity control, the conductive paste on the surfaces of the two electrodes of the ceramic capacitor have diameters between 3 mm and 30 mm and thicknesses between 0.8 mm and 15 mm, the conductive paste is one of a conductive silver paste and a conductive copper paste; and
b) sintering the conductive paste covering each of the two electrodes of the ceramic capacitor and reducing the conductive paste into a reduced electrode selected from a silver and a copper electrode, such that a cross-section of the two electrodes is completely covered with the conductive paste at an outer edge and the corona effect is inhibited.

8. The method according to claim 1, wherein the conductive paste is the conductive silver paste having a viscosity between 10,000 cps and 200,000 cps, the conductive silver paste is completely applied to the cross-section of the two electrodes of the ceramic capacitor in a thickness between 1 μm and 50 μm.

9. The method according to claim 1, wherein the conductive paste is the conductive copper paste having a viscosity between 10,000 cps and 200,000 cp, the conductive silver paste is completely applied to the cross-section of the two electrodes of a ceramic capacitor in a thickness between 1 μm and 50 μm.

10. The method according to claim 1, wherein the sintering step b) is performed at a temperature between 150° C. and 850° C.

11. The method according to claim 1, wherein the sintering step b) includes polishing a leakage electrode layer located on an outer edge of the ceramic capacitor utilizing a polishing wheel having a diameter between 200 μm and 1500 μm at a speed between 5 rpm and 100 rpm, and the leakage electrode layer is polished at a depth between 0.05 mm and 1.0 mm.

12. The method according to claim 1, wherein the conductive paste has a viscosity between 8,000 cps and 150,000 cps, and the surface of each of the two electrodes of the ceramic capacitor has a thickness between 1 μm and 50 μm.

13. The method according to claim 1, further comprising a drying step following the sintering step b), the drying step including drying the reduced electrodes of the ceramic capacitor.
